(19) United States
(12) Patent Application Publication
(10) Pub. No.: US 2005/0040406 A1
(43) Pub. Date: Feb. 24, 2005

(54) Semiconductor light emitting device

(75) Inventor: Daisuke Nakagawa, Kyoto (JP)

Correspondence Address: HOGAN & HARTSON L.L.P., 500 S. GRAND AVENUE, SUITE 1900, LOS ANGELES, CA, 90071-2611, US

(73) Assignee: ROHM CO., LTD.

(21) Appl. No.: 10/889,409

(22) Filed: Jul. 12, 2004

(30) Foreign Application Priority Data
Aug. 20, 2003 (JP) JP2003-207969

(51) Int. Cl. H01L 27/15

(52) U.S. Cl. 257/79

(57) ABSTRACT

In a gallium nitride compound semiconductor, making small the thickness of a metal electrode layer in order to enhance the efficiency of taking light out relatively increases the resistance value of the metal electrode layer as measured in a direction that is parallel with this layer compared to that of it in a direction that is vertical with respect thereto. As a result of this, when a voltage has been applied across relevant electrodes, electric current ceases to be sufficiently supplied to the entire metal electrode layer. The semiconductor light emitting device of the invention is equipped, between the metal electrode layer and an active layer, with a superlattice layer for enhancing the efficiency of taking out the light that has been emitted in the active layer.

### BACKGROUND OF THE INVENTION

The disclosure of Japanese Patent Application No. 2003-207969 filed Aug. 20, 2003 including specification drawings and claims is incorporated herein by reference in its entirety.

### FIELD OF THE INVENTION

The present invention relates to a semiconductor light emitting device that is comprised of a gallium nitride compound semiconductor and, more particularly, to a semiconductor light emitting device that is comprised of a gallium nitride compound semiconductor that is equipped with a superlattice layer.

### DESCRIPTION OF THE RELATED ART

In a semiconductor light emitting device that is comprised of a gallium nitride compound semiconductor that is expressed as AlₓGa_{y}In_{1-x-y}N (where 0≦x≦1, 0≦y≦1, and 0≦x+y≦1), that light emitting device being represented by a blue color light emitting diode, a semiconductor substrate that composes a base of it is unable to be manufactured using bulk crystal that is good in quality and large in size. Therefore, ordinarily, a semiconductor substrate is manufactured by causing a gallium nitride compound semiconductor to be crystal-grown onto a substrate consisting of sapphire (Al₂O₃). And, with respect to over this semiconductor substrate, various kinds of process steps are executed to thereby manufacture that device (for example, refer to Japanese Patent Application Laid-Open No. 62-119196).

FIG. 1 is a schematic view of a conventional semiconductor light emitting device. In FIG. 1, a reference numeral 11 denotes a substrate; a reference numeral 12 denotes an n-type semiconductor layer; a reference numeral 13 denotes an active layer that has a luminous region; a reference numeral 14 denotes a p-type semiconductor layer; a reference numeral 16 denotes a metal electrode layer; a reference numeral 18 denotes an electrode on a side of the p-type semiconductor layer; and a reference numeral 19 denotes an electrode on a side of the n-type semiconductor layer.

The active layer 13 is a layer that has a luminous portion of the semiconductor light emitting device. On a side thereof where the n-type semiconductor layer 12 is located, the light that has been emitted in the active layer 13 is shaded by a base (not illustrated) on which the substrate 11 is placed. Therefore, taking-out of the light emitted in the active layer 13 is performed from the side where the p-type semiconductor layer 14 is located. Therefore, in order to enhance the light taking-out efficiency, it is only necessary to thin the thickness of the metal electrode layer 16 and in addition to make high the light transmittance of that layer 16. Or, alternatively, it is only necessary to form the electrode 19 on an end of the metal electrode layer 16 to thereby make high the intensity of the light, at around the center of the metal electrode layer 16, that has been emitted in the active layer 13. However, when thinning the thickness of the metal electrode layer 16, the resistance value of the metal electrode layer 16 in the direction that is parallel with the metal electrode layer 16 becomes relatively large as compared with that of the metal electrode layer 16 in the direction that is vertical to the metal electrode layer 16. Therefore, when having applied a voltage with respect to the electrode 18, an electric current ceases to be sufficiently supplied to the metal electrode layer 16 as a whole.

Also, when forming the electrode 18 on the end of the metal electrode layer 16, the electric current into the entire metal electrode layer 16 has more difficulty being supplied to the entire metal electrode layer 16 than when having formed the electrode 18 at around the center of the metal electrode layer 16. When an electric current is supplied to part of the metal electrode layer 16, the electric current flows through only a part of the active layer 13 via the p-type semiconductor layer 14. As a result of this, the problem arises that emitting of light (luminescence) occurs only from a part of the active layer 13. On the other hand, when thickning the thickness of the metal electrode layer 16, the light transmittance of the metal electrode layer 16 becomes low. Also, when forming the electrode 18 near the center of the metal electrode layer 16, the electrode 18 shades the light that has been emitted in the active layer 13. As a result of this, the problem arises that the efficiency of taking out the light from the side of the p-type semiconductor layer 14 becomes decreased.

### SUMMARY OF THE INVENTION

The present invention, in order to solve the above-described problems, has an object to provide a semiconductor light emitting device comprised of gallium nitride compound semiconductor, which is equipped with a superlattice layer that contributes to enhancing the efficiency of taking out the light that has been emitted in the active layer.

To attain the above object, according to a first aspect of the invention of this application, there is provided a semiconductor light emitting device comprised of a gallium nitride compound semiconductor expressed as AlₓGa_{y}In_{1-x-y}N (where 0≦x≦1, 0≦y≦1, and 0≦x+y≦1), which comprises on a substrate at least a first conductivity type semiconductor layer, an active layer having a light emitting region, a second conductivity type semiconductor layer, and a metal electrode layer sequentially in this order from the substrate side, and in which a superlattice layer is located at an arbitrary position between the metal electrode layer and the active layer.

In the first aspect of the invention of this application, the superlattice layer is a semiconductor layer that consists essentially of a gallium nitride compound semiconductor that is expressed as AlₚGa_{q}In_{1-p-q}N (where 0≦p≦1, 0≦q≦1, and 0≦p+q≦1) and is the semiconductor layer that has a forbidden band width that is greater than that of the active layer.

In the first aspect of the invention of this application, the second conductivity type semiconductor layer is a p-type semiconductor layer and the metal electrode layer consists of gold (Au), nickel (Ni), or an alloy comprising these elements.

According to a second aspect of the invention of this application, there is provided a semiconductor light emitting device comprised of a gallium nitride compound semiconductor expressed as AlₓGa_{y}In_{1-x-y}N (where 0≦x≦1, 0≦y≦1, and 0≦x+y≦1), which comprises on a substrate at least a first conductivity type semiconductor layer, an active layer having aluminous region, a second conductivity type semiconductor layer, and an electrode sequentially in this order from the substrate side, and in which a superlattice layer is located at an arbitrary position between the electrode and the active layer.

In the second aspect of the invention of this application, the superlattice layer is a semiconductor layer that consists essentially of a gallium nitride compound semiconductor that is expressed as AlₚGa_{q}In_{1-p-q}N (where 0≦p≦1, 0≦q≦1, and 0≦p+q≦1) and is the semiconductor layer that has a forbidden band width that is greater than that of the active layer.

### BRIEF DESCRIPTION OF THE DRAWINGS

FIG. 1 is a schematic view of a conventional semiconductor light emitting device;

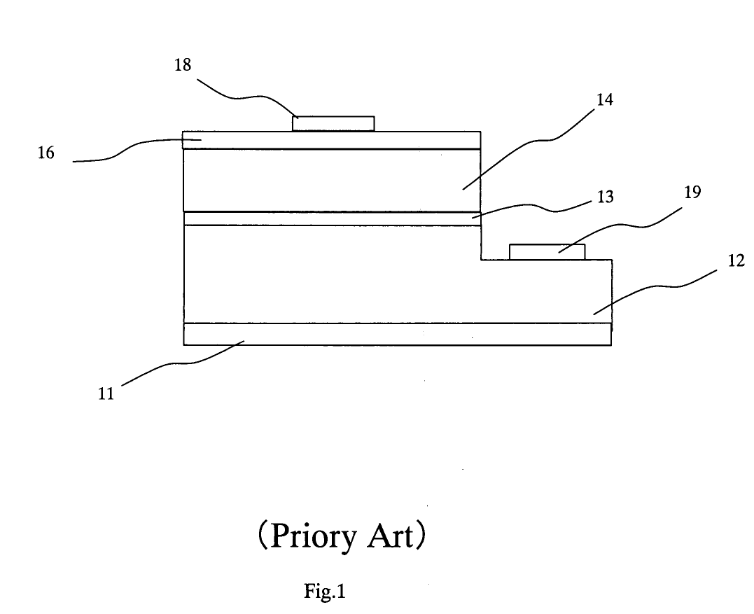

FIG. 2 is a schematic view of a semiconductor light emitting device according to an embodiment of the invention of this application;

FIG. 3 a schematic view of the semiconductor light emitting device according to another embodiment of the invention of this application; and

FIG. 4 is an enlarged schematic view of a superlattice layer.

### DETAILED DESCRIPTION OF THE INVENTION

### DESCRIPTION OF THE PREFERRED EMBODIMENTS

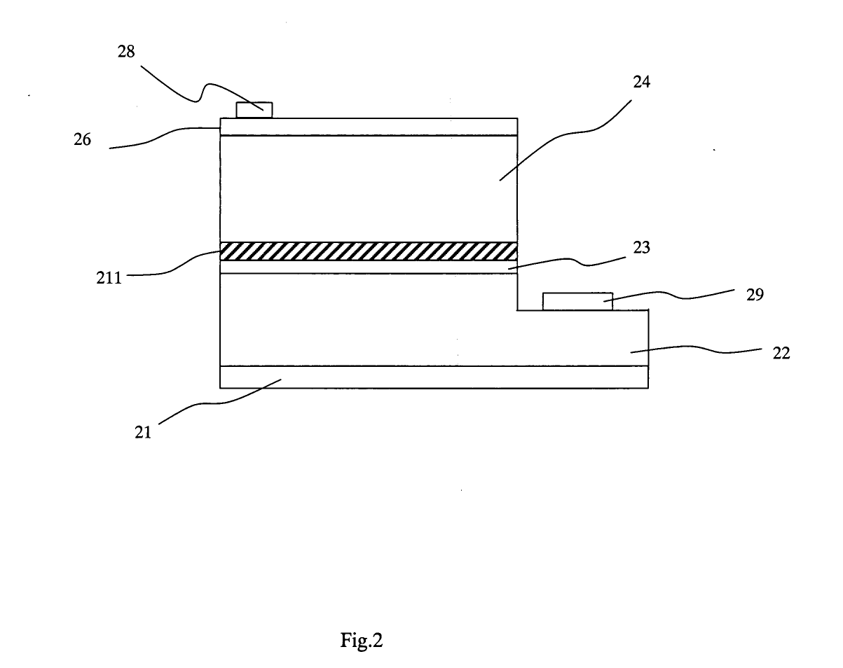

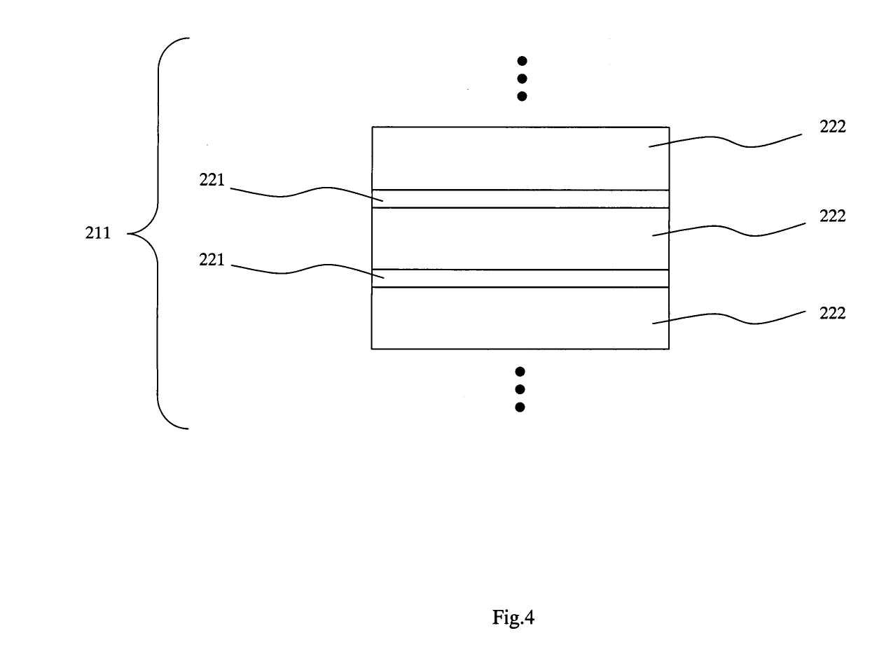

Hereinafter, an embodiment of the invention of this application will be explained with reference to the accompanying drawings. FIG. 2 shows a schematic view of a semiconductor light emitting device that embodies the invention of this application. Also, FIG. 4 shows a schematic view, enlarged, of a superlattice layer. In FIG. 2, a reference numeral 21 denotes a substrate, a reference numeral 22 denotes a first conductivity type semiconductor layer, a reference numeral 23 denotes an active layer that has a luminous region, a reference numeral 24 denotes a second conductivity type semiconductor layer, a reference numeral 26 denotes a metal electrode layer, a reference numeral 28 denotes a second electrode, a reference numeral 29 denotes a first electrode, and a reference numeral 211 denotes the superlattice layer. Also, in FIG. 4, a reference numeral 221 denotes a layer whose forbidden band width is narrow, and a reference numeral 222 denotes a layer whose forbidden band width is wide. The invention of this application has a characterizing feature in that the superlattice layer 211 is provided between the metal electrode layer 26 and the active layer 23. Each of the first conductivity type semiconductor layer 22 and second conductivity type semiconductor layer 24 is an n-type or p-type semiconductor layer, and they are the layers whose polarities of that are opposite to each other.

As the material of the substrate 21, there can be used sapphire, SiC or the like. The reason why using sapphire, SiC or the like is in view of the fact that using a GaN substrate is difficult since GaN has the difficulty of being bulk crystal-grown because of the high dissociation pressure of nitrogen. If the substrate is the one that consists of material that is different from GaN, material therefor is not limited to sapphire and SiC. Also, in a case where using a sapphire substrate as the substrate 21, the principal surface thereof may be a C, R, or A surface.

Here, although, ordinarily, it is surely not impossible to form bulk crystal of GaN with respect to the sapphire substrate as is, in a case where difficult, it is necessary to perform relevant processing with respect to the substrate 21 for forming the first conductivity type semiconductor layer. Those processing that are performed with respect to the substrate 21 include, for example, forming on the surface made of sapphire, using a growth-at-low-temperature technique, a GaN layer having the thickness of several tens of nano-meters (nm), and forming, a GaN layer the thickness of several micro-meters (>m) using a growth-at-low-temperature technique, after forming an AlGaN layer having a thickness of several tens of nano-meters (nm). These substrates each having formed therein such a GaN layer or AlGaN layer are also included under the category of “substrate” that is referred to in this application.

As each of the first conductivity type semiconductor layer 22, active layer 23, and second conductivity type semiconductor layer 24, there is used the one that is comprised of a gallium nitride compound semiconductor that is expressed as AlₓGa_{y}In_{1-x-y}N (where 0≦x≦1, 0≦y≦1, and 0≦x+y≦1). When applying as the first conductivity type semiconductor layer 22, active layer 23, and second conductivity type semiconductor layer 24 the one that is comprised of a gallium nitride compound semiconductor that is expressed as AlₓGa_{y}In_{1-x-y}N (where 0≦x≦1, 0≦y≦1, and 0≦x+y≦1), it is possible to cause light emission over a wide range of wavelengths.

The first conductivity type semiconductor layer 22 may be of a single-layer, or multi-layer, structure. Although in FIG. 2 that layer consists of a single layer that exhibits both functions of a cladding layer and contact layer that makes ohmic contact with the first electrode 29, the cladding layer and contact layer may be formed respectively separately. Further, the first conductivity type semiconductor layer 22 may have a layer that has other function such as a hole barrier layer.

The second conductivity type semiconductor layer 24 may be of a single-layer, or multi-layer, structure. Although in FIG. 2 that layer 24 consists of a layer that exhibits both functions of a cladding layer and contact layer and the superlattice layer 211, the cladding layer and contact layer may be formed respectively separately. Further, the second conductivity type semiconductor layer 24 may have a layer that has other function such as an electron barrier layer.

The active layer 23 may be formed as having a structure that is given in kind, such as a bulk structure, a single quantum well structure, or a multi-quantum well structure. In a case where adopting a single quantum well structure or multi-quantum well structure, it results that as the well layer that composes the single quantum well structure or multi-quantum well structure there is used a layer that is narrow in forbidden band width and as the barrier layer there is used a layer that is wide in forbidden band width. For example, as the well layer, there can be used a layer that consists of material expressed as In₁₋ₐGaₐN (where 0<a≦1), while, as the barrier layer, there can be used a layer that consists of material expressed as Al_{1-b}Ga_{b}N (where 0<b≦1), provided that a×b<1.

In the process steps of forming the active layer 22, it may be constructed in the way that, for example, of the active layer 23, only a portion having the luminous portion as its central region is left as is, namely, as a mesa shaped semiconductor light emitting device. Or, alternatively, it may be constructed in the way that concentrating the electric current by narrowing thereof to cause this relevant portion to function as a luminous portion. For example, in a DFB laser (distributed feedback laser diode) that is used for long-distance/large-capacity transmission, or fabry-perot laser diode that is used centering the subscriber's line transmission, the active layer 23 may be constructed as having a BH (Buried Heterostructure) type structure made as a multi-quantum well structure wherein the active layer has formed therein a multi-layer film. Further, the active layer 23 may be constructed as having an FBH (Flat-surface Buried Heterostructure) type structure that has a great effect of narrowing the electric current.

In a case where utilizing the nature that the electrical conductivity that is measured in the direction that is parallel to the superlattice layer 211 is higher than that which is measured in the direction that is vertical to that layer 211, if the superlattice layer 211 is disposed at a given position between the metal electrode layer 26 and active layer 23, the supply of the electric current to the active layer 23 is uniformly performed, even thinning the thickness of the metal electrode layer 26 more than the conventional one of that layer 26 and, further, as illustrated in FIG. 2, disposing the second electrode 28 on a terminal end of that layer 26. As a result of this, it is possible to more enhance, than in the prior art, the effect of taking out the light, which has been emitted in the active layer 23, from the side where the second conductivity type semiconductor layer 24 is located.

Here, as illustrated in FIG. 4, the superlattice layer 211 may be obtained by superposing a plural number of layer, one upon another, using a hetero-junction. The layer subjected to be superposed is the layer whose thickness is the same as the de Broglie wavelength of electron or hole, or less, such as the layers constitute the superlattice layer 211, for example, the layers 221 narrow in forbidden band width and the layers 222 wide in forbidden band width. When using this superlattice layer 211, since in the layer 221 that is narrow in forbidden band width and layer 222 that is wide in forbidden band width the movement of the electrons or holes is quantized by the energy barrier, the electron or hole movement is made two-dimensional. Therefore, it becomes possible to uniformly disperse the electrons in the superlattice layer 211. As a result of this, it is possible to make large the region in which the light emitted in the active layer 23 becomes uniform.

As the superlattice layer 211, it is preferable to use a semiconductor layer which is comprised of a gallium nitride compound semiconductor that is expressed as AlₚGa_{q}In_{1-p-q}N (where 0≦p≦1, 0≦q≦1, and 0≦p+q≦1) and which has a forbidden band width that is wider than that of the active layer 23. If, using the semiconductor layer which is comprised of a gallium nitride compound semiconductor that is expressed as AlₚGa_{q}In_{1-p-q}N (where 0≦p≦1, 0≦q≦1, and 0≦p+q≦1), it is possible to form the superlattice layer 211 by alternately laminating the layer narrow in forbidden band width with the layer wide in forbidden bandwidth. Also, by making the superlattice layer 211 be a semiconductor layer having the forbidden band width of that is wider than that of the active layer 23, it is possible to efficiently emit the light to outside the semiconductor light emitting device without the light emitted in the luminous region of the active layer 23 being adsorbed into the superlattice layer 211.

Furthermore, although, the superlattice layer 211 is disposed at the position that contacts with the active layer 23 in FIG. 2, the superlattice layer 211 may be disposed at a position that is arbitrary between the metal electrode layer 26 and the active layer 23. For example, the superlattice layer 211 may be disposed in direct contact with the metal electrode layer 26 to thereby make the superlattice layer 211 function as a contact layer.

The term “superlattice” refers to a lattice structure that is formed in such a way that, in general, crystal lattice having a certain length of period is subject to modulation by the periodic structure that is again larger in length of period than that of that crystal lattice. In the invention of this application, the superlattice layer 211 uses a layer that consists of, among the general superlattices, the one that has a structure wherein two layers made of materials the forbidden band widths of that are relatively large in terms of the difference between them are alternately laminated together. In the layer 221 narrow in forbidden band width and layer 222 wide in forbidden band width, which compose the superlattice layer 211, electrons or holes are in a state of being confined. In the invention of this application, the thickness of the layer 221 narrow in forbidden band width and layer 222 wide in forbidden band width, which compose the superlattice layer 211, are made to have the thickness of the de Broglie wavelength, or so, of the electrons or holes, thereby limiting the movement of the electrons or holes in the direction that is vertical to the layer 221 narrow in forbidden band width and layer 222 wide in forbidden band width. Further, by making free the movement of the electrons or holes in the direction that is parallel to the layer 221 narrow in forbidden band width and layer 222 wide in forbidden band width, it becomes possible to have electrons or holes uniformly dispersed in those layer 221 and layer 222. In other words, it is thought that it is possible, in the superlattice layer 211, to make the electrical conductivity in the parallel direction to the superlattice layer 211 higher than that in the vertical direction to the superlattice layer 211.

When forming this superlattice layer, it is necessary that each layer composing it be laminated with its thickness being a critical thickness of approximately 10 nm or less that can resist distortions. By laminating each layer with its thickness being that critical one or less, distortions are mitigated, and crystal defects also are decreased.

Also, although the superlattice layer 211 is comprised of layers that have the same polarity as the second conductivity type semiconductor layer 24, doping is not always needed. Namely, since the gallium nitride compound semiconductor that is expressed as AlₓGa_{y}In_{1-x-y}N (where 0≦x≦1, 0≦y≦1, and 0≦x+y≦1) becomes n-type unless doping is performed with respect thereto, in a case where making the superlattice 211 an n-type, n-type dopant may be doped, or may not be doped.

In this embodiment, in a case where the second conductivity type semiconductor layer 24 is of a p-type, it is preferable that, as the metal electrode layer 26, gold (Au), nickel (Ni), or one of alloys comprising them be applied. It is possible for the metal electrode layer 26 and second conductivity type semiconductor layer 24 to have an ohmic contact therebetween by using gold (Au), nickel (Ni), or one of alloys comprising them as the metal electrode layer 26. This enables supplying the electric current through the second conductivity type semiconductor layer 24 that is low in resistance. In a case where the second conductivity type semiconductor 24 is of an n-type, it is preferable that, as the metal electrode layer 26, titanium (Ti), aluminum (Al), or one of alloys comprising them be applied. Whichever material is applied, the resulting layer 26 becomes transparent, or almost transparent, with respect to the light that has been emitted in the active layer 23.

It is sufficient that the first electrode 29 is electrically connected to the first conductivity type semiconductor layer 22 and it is the one that can be electrically contacted with the first conductivity type semiconductor layer 22. In a case where the first conductivity type semiconductor layer 22 is an n-type one, it is preferable that the first electrode 29 be the one that is comprised of titanium (Ti), aluminum (Al), or one of alloys comprising them. In a case where that layer 22 is a p-type one, it is preferable that, as the first electrode 29, gold (Au), nickel (Ni), or one of alloys comprising them, or an electrode material comprised of ZnO or ITO be applied.

Furthermore, it is preferable that, as illustrated in FIG. 2, part of the first conductivity type semiconductor layer 22 be exposed; and the first electrode 29 be formed on that exposed portion. This is because the manufacturing method involved is made easy. Namely, adopting this structure is preferable in the respect that, after forming all relevant layers, it can be formed only by executing the process steps such as the photolithography, etching or the like. Furthermore, the first electrode 29 is not limited to that position. Needless to say, it would be sufficient if that electrode 29 is provided at a position at which it is electrically connected to the first conductivity type semiconductor layer 22 and which enables exhibiting the effect of the invention of this application.

Regarding the second electrode 28, it may be made of any material only if it is electrically connected to the metal electrode layer 26 and can be brought into ohmic contact with the metal electrode layer 26. For example, as that second electrode 28, gold (Au) or aluminum (Al) can be applied.

Accordingly, if the superlattice layer 211 is disposed at a given position between the metal electrode layer 26 and the active layer 23, supplying the electric current to the active layer 23 becomes uniformly performed. As a result of this, it is possible to make thin the metal electrode layer 26 and to more enhance, than in the prior art, the efficiency of taking out the light, which has been emitted in the active layer 23, from the side where the second conductivity type semiconductor layer 24 is located. Also, even if the second electrode 28 is disposed on an end portion of the metal electrode layer 26, it is possible to cause uniform luminescence of the light from within the active layer 23. As a result of the second electrode 28 being able to be disposed on an end of the metal electrode layer 26, it is possible to more enhance, than in the prior art, the efficiency of taking out the light, which has been emitted in the active layer 23, from the side where the second conductivity type semiconductor layer 24 is located. Furthermore, without providing the second electrode 28, a line of electrode may be bonded directly to the metal electrode layer 26.

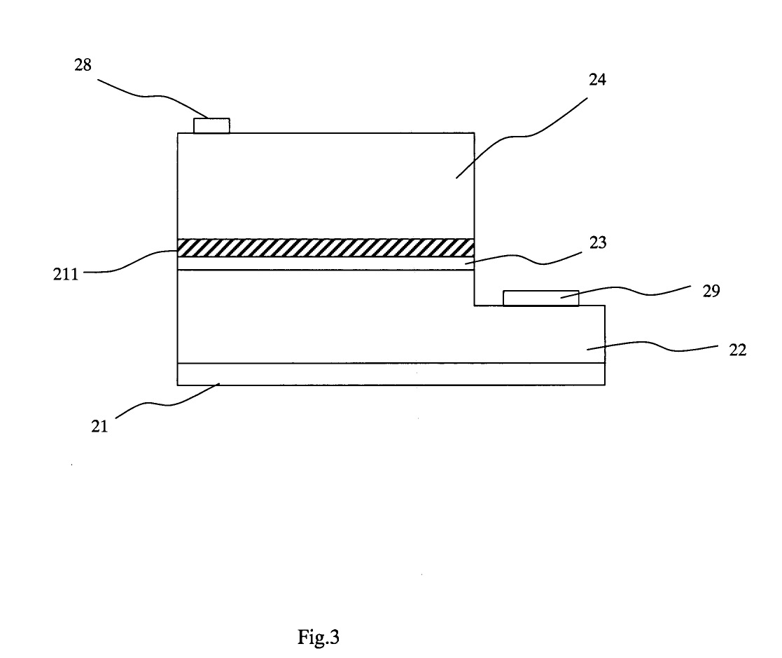

Next, another embodiment of the invention of this application will be explained using FIGS. 3 and 4. The other mode of the invention of this application is a semiconductor light emitting device that has wholly or partly omitted therefrom the metal electrode layer that was provided in the above-described preceding embodiment. If making the most of the function of the superlattice layer 211 which causes the diffusion of the electric current, it is possible to omit the provision of the metal electrode layer wholly or partly. If able to wholly or partly omit the metal electrode layer, it is possible to reduce the manufacturing process steps for the semiconductor light emitting device.

This other embodiment of the invention of this application will be explained with reference to the accompanying drawings. FIG. 3 is a schematic view of the semiconductor light emitting device that embodying the other embodiment of the invention of this application. In FIG. 3, a reference numeral 21 denotes a substrate, a reference numeral 22 denotes a first conductivity type semiconductor layer, a reference numeral 23 denotes an active layer that has a luminous region, a reference numeral 24 denotes a second conductivity type semiconductor layer, a reference numeral 28 denotes a second electrode, a reference numeral 29 denotes a first electrode, and a reference numeral 211 denotes the superlattice layer. Each of the first conductivity type semiconductor layer 22 and second conductivity type semiconductor layer 24 is an n-type or p-type semiconductor layer, and has a polarity that is opposite to that of the other. The invention of this application has a characterizing feature in that the superlattice layer 211 is provided between the second electrode 28 and the active layer 23.

As the material of the substrate 21, sapphire, SiC or the like, can be applied. That material is not limited to sapphire or SiC if it is material that is different from GaN. Also, in a case where using a sapphire substrate as the substrate 21, the principal surface thereof may be a C, R, or A surface.

As each of the first conductivity type semiconductor layer 22, active layer 23, and second conductivity type semiconductor layer 24, there is used the one that is comprised of a gallium nitride compound semiconductor that is expressed as AlₓGa_{y}In_{1-x-y}N (where 0≦x≦1, 0≦y≦1, and 0≦x+y≦1). When applying as the first conductivity type semiconductor layer 22, active layer 23, and second conductivity type semiconductor layer 24 the one that is comprised of a gallium nitride compound semiconductor that is expressed as AlₓGa_{y}In_{1-x-y}N (where 0≦x≦1, 0≦y≦1, and 0≦x+y≦1), it is possible to cause light emission over a wide range of wavelengths.

The first conductivity type semiconductor layer 22 may be of a single-layer, or multi-layer, structure. Although in FIG. 3 that layer consists of a single layer that exhibits both functions of a cladding layer and contact layer that makes ohmic contact with the first electrode 29, the cladding layer and contact layer may be formed respectively separately. Further, the first conductivity type semiconductor layer 22 may have a layer that has other function such as a hole barrier layer.

The second conductivity type semiconductor layer 24 may be of a single-layer, or multi-layer, structure. Although in FIG. 3 that layer 24 consists of a layer that exhibits both functions of a cladding layer and contact layer and the superlattice layer 211, the cladding layer and contact layer may be formed respectively separately. Further, the second conductivity type semiconductor layer 24 may have a layer that has other function such as an electron barrier layer.

The active layer 23 may be formed as having a structure, such as a bulk structure, a single quantum well structure, or a multi-quantum well structure. In a case where adopting a single quantum well structure or multi-quantum well structure, it results that as the well layer that composes the single quantum well structure or multi-quantum well structure there is used a layer that is narrow in forbidden band width and as the barrier layer there is used a layer that is wide in forbidden band width. For example, as the well layer, there can be used a layer that consists of material expressed as In₁₋ₐGaₐN (where 0<a≦1), while, as the barrier layer, there can be used a layer that consists of material expressed as Al_{1-b}Ga_{b}N (where 0<b≦1), provided that a×b<1.

In a case where utilizing the nature that the electrical conductivity that is measured in the direction that is parallel to the superlattice layer 211 is higher than that which is measured in the direction that is vertical to that layer 211, if the superlattice layer 211 is disposed at a given position between the second electrode 28 and active layer 23, the supply of the electric current to the active layer 23 is uniformly performed, even omitting the use of the metal electrode layer and further disposing the second electrode 28 on the end of the second conductivity type semiconductor layer 24 as illustrated in FIG. 3. As a result of this, it is possible to more enhance, than in the prior art, the effect of taking out the light, which has been emitted in the active layer 23, from the side where the second conductivity type semiconductor layer 24 is located.

As the superlattice layer 211, it is preferable to use a semiconductor layer which is comprised of a gallium nitride compound semiconductor that is expressed as AlₚGa_{q}In_{1-p-q}N (where 0≦p≦1, 0≦q≦1, and 0≦p+q≦1) and which has a forbidden band width that is wider than that of the active layer 23. If, using the semiconductor layer which is comprised of a gallium nitride compound semiconductor that is expressed as AlₚGa_{q}In_{1-p-q}N (where 0≦p≦1, 0≦q≦1, and 0≦p+q≦1), it is possible to form the superlattice layer 211 by alternately laminating the layer narrow in forbidden band width with the layer wide in forbidden band width. Also, by making the superlattice layer 211 be a semiconductor layer having the forbidden band width of that is wider than that of the active layer 23, it is possible to efficiently emit the light to outside the semiconductor light emitting device without the light emitted in the luminous region of the active layer 23 being adsorbed into the superlattice layer 211.

Furthermore, although, the superlattice layer 211 is disposed at the position that contacts with the active layer 23 in FIG. 3, the superlattice layer 211 may be disposed at a position that is arbitrary between the second electrode 28 and the active layer 23. For example, the superlattice layer 211 may be disposed in direct contact with the second electrode 28 to thereby make the superlattice layer 211 function as a contact layer.

It is sufficient if the first electrode 29 is electrically connected to the first conductivity type semiconductor layer 22 and is the one that can be contacted with the first conductivity type semiconductor layer 22. In a case where the first conductivity type semiconductor layer 22 is an n-type one, it is preferable that the first electrode 29 be the one that is comprised of titanium (Ti), aluminum (Al), or one of alloys comprising them. In a case where that layer 22 is a p-type one, it is preferable that, as the first electrode 29, gold (Au), nickel (Ni), or one of alloys comprising them, or an electrode material comprised of ZnO or ITO be applied.

Furthermore, it is preferable that, as illustrated in FIG. 3, part of the first conductivity type semiconductor layer 22 be exposed; and the first electrode 29 be formed on that exposed portion. This is because the manufacturing method involved is made easy. Namely, adopting this structure is preferable in the respect that, after forming all relevant layers, it can be formed only by executing the process steps such as the photolithography, etching or the like. Furthermore, the first electrode 29 is not limited to that position. Needless to say, it would be sufficient if that electrode 29 is provided at a position at which it is electrically connected to the first conductivity type semiconductor layer 22 and which enables exhibiting the effect of the invention of this application.

The second electrode 28 may be electrically connected to the second conductivity type semiconductor layer 24 and can be brought into contact with this layer 24. In a case where the second conductivity type semiconductor layer 24 is an n-type one, it is preferable that the layer 24 be the one that is comprised of titanium (Ti), aluminum (Al), or one of alloys comprising them. In a case where that layer 24 is a p-type one, it is preferable that, as the layer 24, gold (Au), nickel (Ni), or one of alloys comprising them, or an electrode material comprised of ZnO or ITO be applied.

Accordingly, if the superlattice layer 211 is disposed at a given position between the second electrode 28 and the active layer 23, supplying the electric current to the active layer 23 is uniformly performed. As a result of this, it is possible to omit the use of the metal electrode layer and to more enhance, than in the prior art, the efficiency of taking out the light, which has been emitted in the active layer 23, from the side where the second conductivity type semiconductor layer 24 is located. Also, even if the second electrode 28 is disposed on an end portion of the second conductivity type semiconductor layer 24, it is possible to cause uniform luminescence of the light in the active layer 23. As a result of the second electrode 28 being able to be disposed on an end of the metal electrode layer 26, it is possible to more enhance, than in the prior art, the efficiency of taking out the light, which has been emitted in the active layer 23, from the side where the second conductivity type semiconductor layer 24 is located.

As has been described above, according to the present invention, as a result of its being equipped with the superlattice layer, it becomes possible to make the electrode layer thin and, further, omit the use of it wholly or partly. And, it is possible to more enhance the efficiency of taking out the light emitted in the active layer, than in the prior art. Also, it becomes possible to dispose the second electrode on an end of the electrode layer.

1. A semiconductor light emitting device comprised of a gallium nitride compound semiconductor expressed as AlₓGa_{y}In_{1-x-y}N (where 0≦x≦1, 0≦y≦1, and 0≦x+y≦1),
comprising on a substrate at least a first conductivity type semiconductor layer, an active layer having a light emitting region, a second conductivity type semiconductor layer, and a metal electrode layer sequentially in this order from the substrate side,
and a superlattice layer being located at an arbitrary position between the metal electrode layer and the active layer.

2. A semiconductor light emitting device comprised of a gallium nitride compound semiconductor expressed as AlₓGa_{y}In_{1-x-y}N (where 0≦x≦1, 0≦y≦1, and 0≦x+y≦1),
comprising on a substrate at least a first conductivity type semiconductor layer, an active layer having a light emitting region, a second conductivity type semiconductor layer, and an electrode sequentially in this order from the substrate side,
and a superlattice layer being located at an arbitrary position between the electrode and the active layer.

3. A semiconductor light emitting device according to claim 1 or 2, wherein
the superlattice layer is a semiconductor layer that consists essentially of a gallium nitride compound semiconductor that is expressed as AlₚGa_{q}In_{1-p-q}N (where 0≦p≦1, 0≦q≦1, and 0≦p+q≦1) and is the one that has a forbidden band width that is wider than that of the active layer.

4. A semiconductor light emitting device according to claim 1, wherein
the second conductivity type semiconductor layer is a p-type semiconductor layer and the metal electrode layer consists essentially of gold (Au), nickel (Ni), or one of alloys comprising these elements.
